(19) United States
(12) Patent Application Publication
(10) Pub. No.: US 2025/0292993 A1
(43) Pub. Date: Sep. 18, 2025

(54) CHARGED PARTICLE BEAM DEVICE

(71) Applicant: Hitachi High-Tech Corporation, Tokyo (JP)

(72) Inventors: Shunya TANAKA, Tokyo (JP); Hirokazu TAMAKI, Tokyo (JP); Tatsuro IDE, Tokyo (JP)

(21) Appl. No.: 18/860,091

(22) PCT Filed: Jun. 21, 2022
(86) PCT No.: PCT/JP2022/024624

§ 371 Date: Oct. 25, 2024

(51) Int. Cl. H01J 37/21; H01J 37/153; H01J 37/22; H01J 37/26; H01J 37/28

(52) U.S. Cl. CPC H01J 37/21; H01J 37/153; H01J 37/222; H01J 37/265; H01J 37/28; H01J 2237/1532; H01J 2237/216

(57) ABSTRACT

In order to adjust a just focus search range according to a defocus state at a start of an AF and automatically complete a focus adjustment quickly, precisely, and stably, the invention provides a charged particle beam device and a sample observation method, in which a defocus process is performed on one captured image, a magnification for an observation object is changed according to a first image blur amount calculated from a change amount of a sharpness and a value of the first image blur amount, a defocus amount is calculated using a second image blur amount calculated based on an imaging condition for the observation object, and a first excitation current value is determined using the defocus amount and an AF for the observation object is started using the first excitation current value.

### TECHNICAL FIELD

The present invention relates to a charged particle beam device and a sample observation method for performing an observation by irradiating a sample with a charged particle beam.

### BACKGROUND ART

In recent years, more advanced development has been carried out in development sites including semiconductors, materials, and bio-fields. In the development sites, development in a faster cycle is required, and it is necessary to understand a phenomenon related to performance. Since a scanning electron microscope (SEM) can easily observe various samples on the order of nanometers, the SEM is an essential tool in the development sites in various fields. A SEM observation procedure is roughly divided into a sample preparation, a search for a field of view, and an optical axis adjustment. The optical axis adjustment is a necessary operation for obtaining a clear image, and in the optical axis adjustment, the focus adjustment is an operation performed many times in the search for a field of view. Therefore, a time required for the focus adjustment greatly affects a time required for the entire SEM observation. In response to this, many SEMs have an auto focus (AF) function. In the AF, basically, a sharpness representing how clear an image is is calculated while changing a focal position, and a position where the sharpness is highest is set as a just focus. However, a focus search range for the AF is often associated with an observation condition such as an observation magnification, and the focal position at which the AF is started is not often taken into account. Therefore, when the search range is narrow, the AF ends in a short time, but the just focus often is not present in the search range, and a success rate of the AF decreases. On the other hand, when the search range is wide, the success rate of the AF is high, but since the number of SEM images whose sharpness can be evaluated per second is fixed, focus adjustment accuracy is reduced or a required time is increased. That is, since adjustment accuracy, an adjustment speed, and the success rate of the AF are in a tread-off relationship, it is difficult to increase the speed while maintaining the adjustment accuracy of the AF.

In response to this, PTL 1 discloses, for example, a technique as a method of speeding up while maintaining the adjustment accuracy of the AF. This publication provides a technique of estimating a defocus amount at the start of the AF and narrowing a search range, thereby increasing the speed while maintaining the adjustment accuracy of the AF. In PTL 1, the defocus amount at the start of the AF is estimated by calculating a blur amount of an image at a start of the AF using two different images in a blur state and referring to a correlation table between the blur amount and a true defocus amount.

### CITATION LIST

### Patent Literature

PTL 1: JP2016-218206A

### SUMMARY OF INVENTION

### Technical Problem

However, when the method in PTL 1 is applied to a charged particle beam device such as the SEM, there are the following two problems. The first problem is a response delay that occurs when the focus adjustment is performed. In the charged particle beam device such as the SEM, since the focal position is adjusted by controlling an excitation current flowing through an electromagnetic lens, it is necessary to wait until an image is stabilized after the focal position is changed. Therefore, it takes time to obtain two images having the different blur states as in PTL 1, and the AF cannot be speeded up.

The second problem is a height of the observation magnification in the charged particle beam device. PTL 1 assumes a case of using an optical system such as a camera, and when a zoom magnification is about 10 times, an influence 4 observation magnification on the calculation of the blur amount of the image is small. On the other hand, since the zoom magnification of the charged particle beam device is significantly more than 1000 times, the blur amount of the image may not be appropriately calculated when the observation magnification is high. That is, at a high observation magnification, the focal position at the start of the AF often corresponds to a first defocus range described in PTL 1, and there is a problem that the magnitude of the blur amount is not appropriately calculated.

The invention has been made in view of the above problems, and an object thereof is to provide a charged particle beam device that can stably perform the AF at high speed and with high accuracy regardless of the observation magnification for performing the AF and the blur state.

### Solution to Problem

In order to achieve the above object, the invention provides a charged particle beam device having a configuration in which a defocus process is performed on one captured image, a defocus amount is calculated using a first image blur amount calculated from a change amount of a sharpness and a second image blur amount calculated based on an imaging condition for an observation object, a first excitation current value is determined using the defocus amount, and a focus adjustment for the observation object is started using the first excitation current value.

In order to achieve the above object, the invention provides a sample observation method including: a step of performing a defocus process on one captured image; a step of changing a magnification for an observation object according to a first image blur amount calculated from a change amount of a sharpness and a value of the first image blur amount; a step of calculating a defocus amount using a second image blur amount calculated based on an imaging condition for the observation object; and a step of determining a first excitation current value using the defocus amount and starting an AF for the observation object using the first excitation current value.

### Advantageous Effects of Invention

According to the invention, even when the observation magnification is high as in the charged particle beam device, it is possible to stably complete the AF at high speed and with high accuracy regardless of the focal position at the time of the start of the AF.

Specifically, in comparison with the high-accuracy AF for searching a narrow range in the related art, the adjustment speed is approximately doubled while maintaining the adjustment accuracy, and the success rate of the AF is improved. In addition, in comparison with an AF for searching a wide range in the related art, the about doubled adjustment accuracy and the about doubled adjustment speed are implemented while maintaining the success rate of the AF. Accordingly, throughput of the focus adjustment and an observation of the charged particle beam device is improved.

### BRIEF DESCRIPTION OF DRAWINGS

FIG. 1 is a configuration diagram of a charged particle beam device according to the invention.

FIG. 2 is a diagram showing an example of a GUI of an input display unit.

FIG. 3 is a diagram showing an example of a flowchart of an entire AF.

FIG. 4 is a diagram showing an example of a flowchart of a method of calculating an image blur amount.

FIG. 5 is a diagram showing an example of a flowchart of a defocus amount estimation.

FIG. 6 is a diagram showing an example of a flowchart of a defocus direction determination.

FIG. 7 shows diagrams of a relationship between an image sharpness and a defocus state in longitudinal and lateral directions before and after introducing astigmatism (longitudinal and lateral directions).

FIG. 8 is a diagram showing an example of a flowchart of a focus adjustment.

### DESCRIPTION OF EMBODIMENTS

Hereinafter, an embodiment of a charged particle beam device and a sample observation method according to the invention will be described with reference to the drawings.

### Embodiment 1

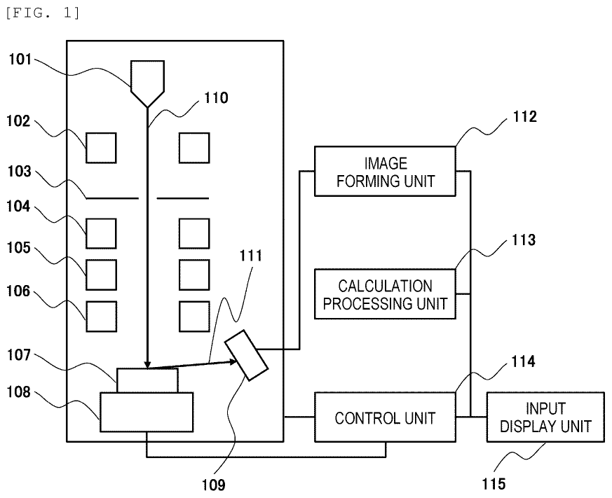

First, a configuration of a charged particle beam device (hereinafter, referred to as the device) that performs a sample observation method will be described with reference to FIG. 1.

As shown in FIG. 1, the device includes an electron gun 101 that emits an electron beam, a focusing lens 102, a diaphragm 103, a deflection coil 104, a stigma coil 105, an objective lens 106, a sample stage 108, a secondary electron detector 109, and an image forming unit 112. The electron gun 101 emits an electron beam 110, the focusing lens 102 and the objective lens 106 finely focus the electron beam, the diaphragm 103 adjusts an opening angle of the electron beam, and the deflection coil 104 performs scanning of the electron beam 110 and deflection of an emitting direction. The secondary electron detector 109 detects secondary electrons 111 generated when an observation sample 107 is irradiated with the electron beam 110. The image forming unit 112 can form a charged particle beam image based on a signal of the secondary electron detector 109, and transmit the image to a calculation processing unit 113. The electron beam 109 may be a charged particle beam such as an ion beam, the secondary electrons 110 may be reflected electrons or transmitted electrons, and the secondary electron detector 108 may be a reflected electron detector or a transmitted electron detector.

In addition, the device includes the calculation processing unit 113 that processes the image transmitted from the image forming unit 112 and calculates a blur amount and a defocus amount. The calculation processing unit 113 calculates the blur amount and the defocus amount based on the image transmitted from the image forming unit 112 and parameters transmitted from a control unit 114, then calculates a value of an excitation current value which is a parameter of the objective lens corresponding to a focal position at which a search for a just focus is started, and transmits the value to the control unit 114.

The device includes the control unit 114 that controls parameters related to the electron optical systems 101 to 106 and the sample stage 108. In particular, parameters related to the deflection coil 104 may be adjusted to change an observation magnification, the stigma coil 105 may be adjusted to perform an astigmatism correction, and parameters related to the objective lens 106 may be adjusted to change the focal position. The control unit 114 can acquire and hold parameters related to the electron optical systems 101 to 106, and can transmit the parameters to the calculation processing unit 113.

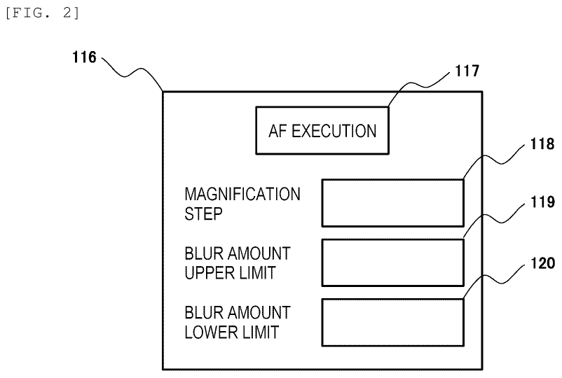

In addition, the device includes an input display unit 115 on which a measurer can input parameters necessary for AF execution and which displays a button for the measurer to start the AF execution. FIG. 2 shows an example of a graphical user interface (GUI) 116 of the input display unit 115, and the GUI 116 includes an AF start button 117, a magnification step input field 118 for specifying a change amount of the observation magnification, which is used when adjusting the observation magnification to an observation magnification appropriate for calculating the blur amount, a blur amount upper limit input field 119 and a blur amount lower limit input field 120 for determining whether the blur amount is appropriately calculated.

An input to the input display unit 115 is not necessarily in the form of the GUI 116, and a method of reading and reflecting a text file may be adopted.

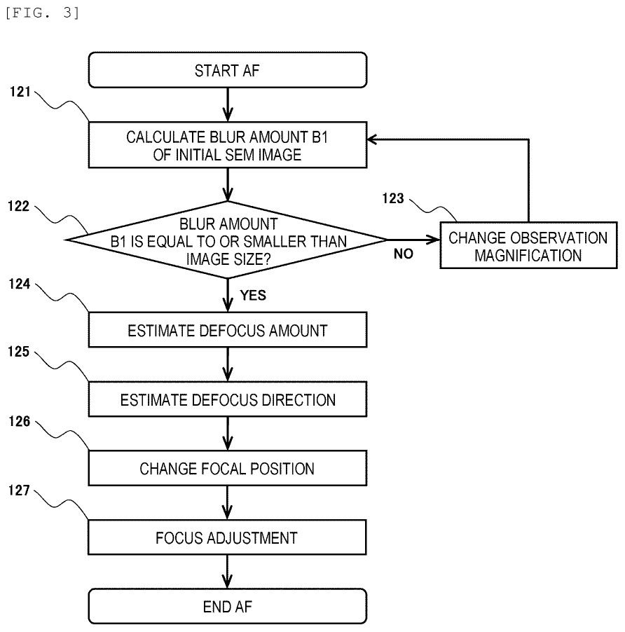

Next, the sample observation method implemented by the device will be described. FIG. 3 is a diagram showing an example of a flowchart of the entire AF according to Embodiment 1.

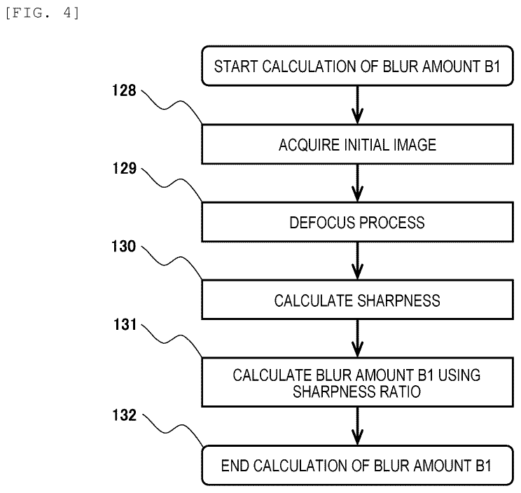

First, a first image blur amount B1 of an initial SEM image necessary for a defocus amount estimation at a start of the AF is calculated (121). FIG. 4 is a diagram showing an example of a flowchart of a method of calculating the first image blur amount B1. In FIG. 4, first, the initial SEM image immediately after the start of the AF is acquired from the image forming unit 112 (128) and transmitted to the calculation processing unit 113.

Next, the calculation processing unit 113 performs a defocus process 129 on the acquired SEM. The defocus process is basically performed using Gaussian blur. Any value of 0 or more may be used as a value of a standard deviation b indicating a blur amount obtained by the Gaussian blur.

The calculation processing unit 113 calculates the first image blur amount B1 of an original initial SEM image using two images which are the original initial SEM image and the initial SEM image subjected to the defocus process (131). The first image blur amount B1 is calculated by calculating a sharpness of each of the original initial SEM image and the initial SEM image subjected to the defocus process (129) (130) and using a sharpness ratio (131).

In the AF used in an optical system such as a camera, the blur amount is calculated using images acquired at a plurality of different focal positions as in, for example, PTL 1. However, in a charged particle beam device such as the SEM, an objective lens using a magnetic field is often adopted, and in order to acquire the images at the plurality of focal positions, it is necessary to wait for several seconds until the magnetic field is stabilized. In the present embodiment, this problem is solved by calculating the blur amount using the two images of the initial SEM image and the initial SEM image subjected to the defocus process by the calculation processing unit 113.

The method of calculating the first image blur amount B1 (131) will be described in detail. A boundary between regions present in an image having no blur is described by a step function U. A luminance F(x) near the boundary in the SEM image can be expressed as F(x,y)=CU(x)+D. Here, x is coordinates of a pixel, and C and D are constants. Further, U(x) takes 1 when x≥0, and takes 0 when x<0. When it is assumed that a blur of an image formed by the charged particle beam device such as the SEM is modeled by a point spread function, an SEM image I₀ having a blur amount B is expressed as I₀(x,y)=F(x,y)×G(B). Here, x represents a convolution product, and G represents a kernel used for the Gaussian blur.

Next, a method of obtaining B using this formula will be described. First, the defocus process for I₀(x, y) is considered. When the image after being subjected to the defocus process is I₁(x, y), I₁(x,y)=I₀(x,y)×G(b). Here, b represents a blur amount used in the defocus process. Next, a derivative of I₁(x, y) is considered. According to ∇I₁(x,y)=∇((CU(x)+D)×G(B)×G(b)), ΔI₁(x,y)=C(2π(b²+B²))^{-0.5}exp(−x²/2(b²+B²)) can be obtained. A derivative of I₀ (x, y) is also calculated in the same manner, and ∇I₀/∇I₁ as a ratio of absolute values of the differentials of ∇I₀ and ∇I₁ is ((b²+B²)/B²)^{-0.5} exp(−x²/2B²+x²/2(b²+B²)). Here, it can be seen that ∇I₀/∇I₁ takes a maximum value when x=0, a maximum ratio R is (b²+B²)/B²)^{-0.5}, and thus it can be seen that the value does not depend on a pixel coordinate x. That is, when B=b(R²−1)^{-0.5} and the blur amount b of the defocus process performed on I₀(x, y) and R are known, the blur amount B of the original image can be calculated.

Therefore, the calculation processing unit 113 calculates a ratio of differential values of the original initial SEM image and the initial SEM image subjected to the defocus process for each pixel, and acquires the maximum ratio in a vicinity of the boundary, so that R can be obtained. For example, there is a method of defining an average value of values obtained by max pooling with a pixel size of 10×10 as R. When a noise of the image is large and it is expected that the ratio of the differential values is not maximized in the vicinity of the boundary, only the differential values derived from an edge may be acquired by combining an edge enhancement process and the like.

Further, the differential value of the image is not necessarily a value calculated by a differential operation. The blur amount can be calculated using the sharpness ratio, which is a value proportional to the differential value of the image, as in the case of the differential value. For example, the sharpness defined by using a frequency analysis method such as Fourier transform or wavelet transform may be used.

It is determined whether a magnitude of the first image blur amount B1 calculated in the above manner is appropriate. In a case of the charged particle beam device such as the SEM that performs an observation at a high observation magnification, the blur amount is often larger than an image size. In this case, the differential value or the sharpness may not be appropriately calculated, and the first image blur amount may not be appropriately calculated. Therefore, when the first image blur amount is too large with respect to the image size, an operation of deceasing the observation magnification is performed until the first image blur amount B1 becomes smaller than the image size. Accordingly, the blur amount on the SEM image is reduced, and a more appropriate blur amount can be calculated as compared with a case where the magnification is high. Conversely, when the first image blur amount B1 calculated by excessively decreasing the observation magnification becomes finely small, the blur amount calculated by increasing the observation magnification may be increased. In the determination of whether the first image blur amount B1 is appropriate, the blur amount upper limit 119 and the blur amount lower limit 120 input to the GUI 116 of the input display unit 115 are used.

When the initial SEM image has a depth as the magnification is decreased, the first image blur amount may be estimated around a field of view where an initial image is acquired during the start of the AF.

Next, a method of estimating a defocus amount D1 using the first blur image amount B1 after the first image blur amount B1 becomes an appropriate value for the image size will be described.

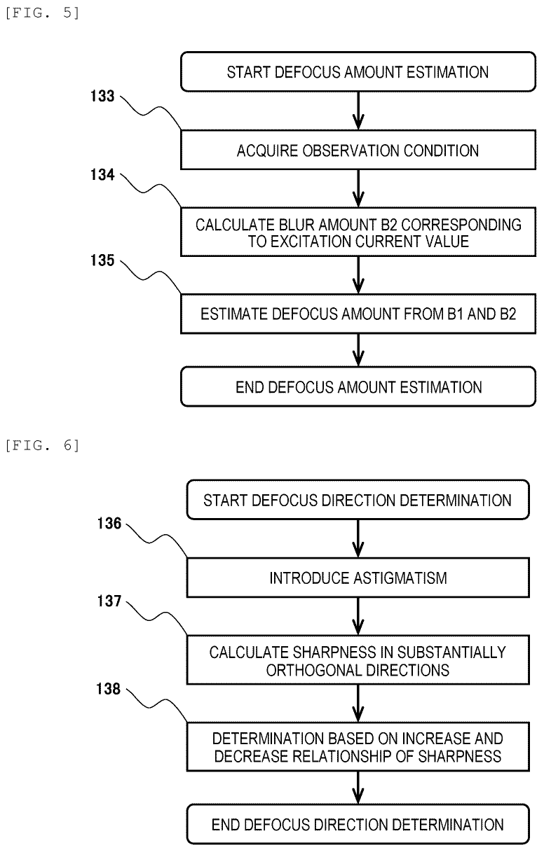

FIG. 5 is a diagram showing an example of a flowchart of the defocus amount estimation.

First, the control unit 114 acquires observation conditions such as parameters related to an opening angle α of the electron beam 110 (133). The parameters are transmitted to the calculation processing unit 113, and the calculation processing unit 113 calculates a correlation between an excitation current value and a second image blur amount B2 on the SEM image based on the parameters (134). For example, when a distance between the objective lens and an object plane is d1, a distance between the objective lens and an image plane is d2, an opening angle of the electron beam on the object plane is α₀, the observation magnification is m, and the defocus amount with the sample is D, the second image blur amount B2 is calculated as mDα₀d1/d2(i). Here, i represents the excitation current value.

Finally, the calculation processing unit 113 can calculate the defocus amount D1 from the first image blur amount B1 as the excitation current value by referring to the calculated second image blur amount B2 (135).

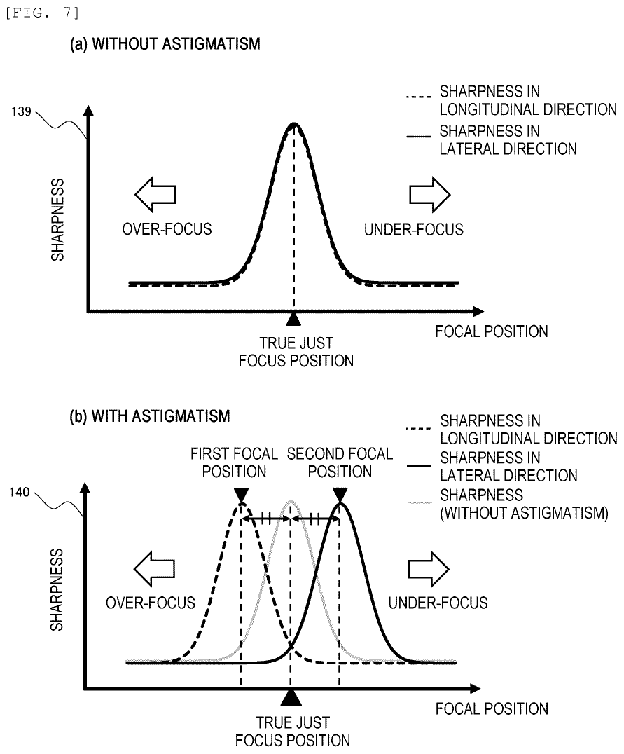

FIG. 6 is a diagram showing an example of a flowchart of a defocus direction determination.

Next, in order to determine a position where a focus adjustment is started, it is necessary to determine a defocus direction. Since the calculated defocus amount D1 is an absolute value, it cannot be determined whether the focal position is on an upper side (over-focus) or a lower side (under-focus) of the sample at the start of the AF. Therefore, it is necessary to determine the defocus direction corresponding to a sign of the defocus amount.

In order to determine the defocus direction, astigmatism is intentionally introduced. Normally, when performing the focus adjustment, a state is desirable in which the astigmatism is appropriately corrected, and when the astigmatism remains, two just focus positions appear. Focusing at each of the two just focus positions is fit in substantially orthogonal directions. For example, it is a state in which the focusing is fit in a longitudinal direction at one just focus position, and the focusing is fit in a lateral direction at the other just focus position. A middle point of the two just focus positions is a true just focus position, and a position where the focusing of the true just focus position is fit forward and backward changes in the substantially orthogonal directions. That is, the defocus direction can be estimated by determining the direction in which the focusing is more fit when the astigmatism is introduced.

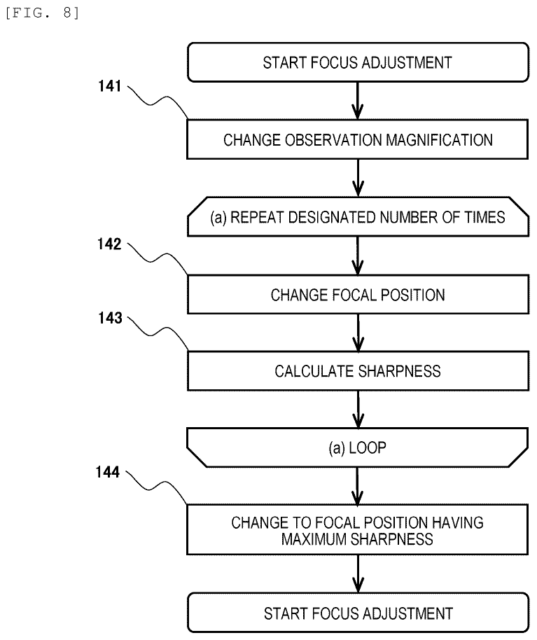

FIG. 7 shows a relationship between an image sharpness and a defocus state in the longitudinal and lateral directions before and after introducing the astigmatism (longitudinal and lateral directions). (a) of FIG. 7 shows a case where there is no astigmatism, and (b) of FIG. 7 shows a case where there is the astigmatism.

The sharpness is an index indicating how clear the image is, and in the present embodiment, the sharpness is defined to be maximum at a position where the focusing is the best. When the astigmatism is appropriately corrected, the longitudinal and lateral sharpness is maximum at the true just focus position. On the other hand, when the astigmatism is introduced, two focal points appear before and after the true just focus position, and the middle point thereof is the true just focus position.

Further, it can be seen that states of increase and decrease in the sharpness are reversed on an over-focus side and an under-focus side. On the over-focus side, the sharpness in the longitudinal direction increases and the sharpness in the lateral direction decreases, whereas on the under-focus side, the sharpness in the lateral direction increases and the sharpness in the longitudinal direction decreases. By using this relationship, the defocus direction can be determined. In the case of the present embodiment, the astigmatism is introduced by using the stigma coil 105 that corrects the astigmatism, and the defocus direction is determined by determining the defocus direction as the over-focus when a sharpness increase amount in the longitudinal direction is larger than that in the lateral direction before and after the introduction and determining the defocus direction as the under-focus when the sharpness increase amount in the lateral direction is larger than that in the longitudinal direction.

In addition, with respect to a stabilization time, which is a problem when the excitation current value of the objective lens 106 is changed, generally, a stigma coil that corrects the astigmatism has a smaller number of turns and a shorter stabilization time than those of the objective lens, and thus the stabilization time is not a problem with the introduction of the astigmatism.

The defocus direction may be determined by shifting the objective lens or the sample stage 108 toward the focal position and increasing or decreasing the sharpness.

Based on the estimated defocus amount D1 and the defocus direction, the calculation processing unit 113 calculates the excitation current value corresponding to the focal position resulting in the just focus position, and transmits the excitation current value to the control unit 114. The control unit 114 changes the excitation current value to the transmitted excitation current value.

Next, the focus adjustment is performed by searching for the just focus position while finely changing the focal position. FIG. 8 is a diagram showing an example of a flowchart of the focus adjustment.

First, the control unit 114 returns the observation magnification to a value at the start of the AF. After the magnification is returned, the defocus amount D2 and the defocus direction are estimated in the same procedure as described above. The search for the just focus is started according to the estimated results. For example, while continuously changing the focal position or the excitation current value, the acquisition of the SEM image and the calculation of the sharpness of the SEM image are repeated, and the focal position at the excitation current value at which the sharpness is the maximum is searched for as the just focus position. After the search, the AF is completed by changing the excitation current value to a value resulting in the just focus position.

According to the invention described in detail above, since a just focus search range can be adjusted according to the defocus amount at the start of the AF, the automatic focus adjustment can be performed stably at high speed and with high accuracy.

The invention is not limited to the embodiments described above, and includes various modifications. For example, the above embodiments have been described for easy understanding of the invention, and the invention is not necessarily limited to those including all the configurations described above. A part or all of the configurations, calculation processing units, control units, and the like described above may be implemented by hardware by, for example, designing with an integrated circuit.

### REFERENCE SIGNS LIST

101: electron gun
102: focusing lens
103: diaphragm
104: deflection coil
105: stigma coil
106: objective lens
107: sample
108: sample stage
109: secondary electron detector
110: electron beam
111: secondary electron
112: image forming unit
113: calculation processing unit
114: control unit
115: input display unit
116: GUI of input display unit
117: AF execution start button
118: magnification step input field
119: blur amount upper limit input field
120: blur amount lower limit input field
139: correlation between sharpness and focal position when there is no astigmatism
140: correlation between sharpness and focal position when there is astigmatism

1. A charged particle beam device, wherein
a defocus process is performed on one captured image,
a defocus amount is calculated using a first image blur amount calculated from a change amount of a sharpness and a second image blur amount calculated based on an imaging condition for an observation object,
a first excitation current value is determined using the defocus amount, and
a focus adjustment for the observation object is started using the first excitation current value.

2. The charged particle beam device according to claim 1, wherein
a magnification for the observation object is changed according to a value of the first image blur amount, and the calculation of the first image blur amount is repeated.

3. The charged particle beam device according to claim 1, wherein
in addition to the defocus amount, a defocus direction is estimated by introducing astigmatism or shifting a focal position, the first excitation current value is determined using the defocus amount and the defocus direction, and the focus adjustment for the observation object is started using the first excitation current value.

4. The charged particle beam device according to claim 1, further comprising:
an electron gun configured to emit an electron beam;
a focusing lens configured to focus the electron beam;
a diaphragm;
a deflection coil;
a stigma coil;
an objective lens;
a sample stage; and
a secondary electron detector.

5. The charged particle beam device according to claim 4, further comprising:
an image forming unit configured to form an image based on an output of the secondary electron detector;
a calculation processing unit configured to process the image;
an input display unit configured to display outputs of the image forming unit and the calculation processing unit; and
a control unit.

6. The charged particle beam device according to claim 5, wherein
the control unit controls the focusing lens based on
the first excitation current value.

7. The charged particle beam device according to claim 5, wherein
the control unit changes a magnification for the observation object according to a value of the first image blur amount, and performs control to repeat the calculation of the first image blur amount.
